(19) United States
(12) Patent Application Publication
(10) Pub. No.: US 2026/0029492 A1
(43) Pub. Date: Jan. 29, 2026

(54) TMR SENSOR WITH SENSING MULTILAYER STRUCTURE

(71) Applicant: Infineon Technologies AG, Neubiberg (DE)

(72) Inventors: Bernhard ENDRES, Nabburg (DE); Apoorva SHARMA, Unterensingen (DE)

(21) Appl. No.: 19/275,527

(22) Filed: Jul. 21, 2025

(30) Foreign Application Priority Data
Jul. 29, 2024 (DE) 102024121570.4

(51) Int. Cl. G01R 33/09; G01R 33/00

(52) U.S. Cl. CPC G01R 33/098; G01R 33/0052

(57) ABSTRACT

A magnetoresistive sensor includes a substrate, a reference system formed on the substrate, a tunnel barrier formed on the reference system, and a multilayer sensing structure formed on the tunnel barrier. The multilayer sensing structure includes a plurality of layers with at least one seed layer and at least one layer of ferromagnetic material with a saturation magnetization of at least 1.5 Tesla.

### CROSS-REFERENCE TO RELATED APPLICATION

This application claims priority to Germany Patent Application No. 102024121570.4 filed on Jul. 29, 2024, the content of which is incorporated by reference herein in its entirety.

### FIELD

The present disclosure relates to the field of Tunnel MagnetoResistance (TMR) sensors, specifically configured for applications requiring high linear range in magnetic field sensing, such as linear position measurement, for example. In particular, the present disclosure relates to TMR sensors featuring a multilayered free layer for a high linear sensing range.

### BACKGROUND

A TMR-based magnetic field sensor is a device that measures magnetic fields using the tunnel magnetoresistance (TMR) effect. It comprises of multiple thin layers of materials, including a tunnel barrier and ferromagnetic layers. When a magnetic field is applied, the resistance of the sensor changes. This change in resistance may be used to detect the strength and/or direction of the magnetic field. TMR sensors are known for their high sensitivity and accuracy. They may be used in various applications, such as automotive systems, industrial machinery, and consumer electronics.

TMR-based magnetic field sensors have high accuracy and low power consumption but may lack the possibility for a high linear range. For vortex-based sensors, the linear range can either be increased by increasing the free layer (FL) thickness t or reducing the diameter D. A vortex-based sensor may detect magnetic fields using a special magnetic state called a vortex. In this state, the magnetization of the free layer may form a circular pattern with a core pointing up or down. This vortex state may be stable and allow the sensor to measure magnetic fields accurately. These sensors may be configured to have a high linear range and can handle stronger magnetic fields without losing accuracy. Due to technical limitations within process integration, the FL thickness cannot be increased at will. In addition, increasing the FL thickness may be expensive because of deposition and etching time. On the other hand, the reduction of the diameter may also be limited, e.g., by lithography.

Thus, there is a need for further increasing the linear range of TMR-based magnetic field sensors.

### SUMMARY

This need is addressed by TMR sensors and methods in accordance with the appended claims.

According to a first aspect, the present disclosure provides a TMR sensor. The TMR sensor includes a substrate, a reference system formed on the substrate, a tunnel barrier formed on the reference system, and a multilayer sensing structure formed on the tunnel barrier. The multilayer sensing structure includes least one seed layer structure and at least one polycrystalline layer of ferromagnetic material with a saturation magnetization (μ0 Ms) of at least 1.5 Tesla, preferably more than 1.6 Tesla. Such a TMR sensor can measure magnetic fields accurately within a high linear range. The ferromagnetic material with a high saturation magnetization may help detecting strong magnetic fields. The seed layer structure may help the ferromagnetic material grow properly with low grain size to have a preferably soft magnetic sensing layer with low hysteresis. The proposed structure may make the sensor reliable and efficient.

In some implementations, the seed layer structure may include a single seed layer, for example a Ru layer. Alternatively, the seed layer structure may include a first seed layer (e.g., Ta) and a second seed layer (e.g., NiFe) on top of the first seed layer. This means that the seed layer structure in the device can either consist of a single seed layer, such as a layer of ruthenium (Ru), or it can be a combination of two seed layers. In the latter case, the first seed layer could be made of tantalum (Ta), and the second seed layer, made of nickel-iron (NiFe), would be placed on top of the first seed layer. The polycrystalline layer of ferromagnetic material may be formed on top of the seed layer structure.

In some implementations, the multilayer sensing structure includes at least three layers. For example, the multilayer sensing structure may include a lattice matching ferromagnetic layer (e.g., CoFeB) with a lattice structure matching a lattice structure of the tunnel barrier (e.g., MgO). This means that the multilayer sensing structure may include a ferromagnetic layer, such as cobalt-iron-boron (CoFeB), which has a crystal lattice structure that matches the crystal lattice structure of the tunnel barrier, such as magnesium oxide (MgO). This lattice matching may ensure that the atomic arrangement of the ferromagnetic layer aligns well with the atomic arrangement of the tunnel barrier. One advantage of this lattice matching is that it may reduce lattice strain and defects at the interface between the ferromagnetic layer and the tunnel barrier. This may result in a smoother and more coherent interface, which may improve the electron tunneling efficiency and enhances the overall performance of the TMR sensor, leading to high sensitivity and reliability in measuring magnetic fields. The lattice matching ferromagnetic layer may be formed on the tunnel barrier. The multilayer sensing structure may further include at least one seed layer (structure) (e.g., Ru, Ta or a combination of Ta/NiFe) formed on top of the lattice matching ferromagnetic layer. The multilayer sensing structure may further include the polycrystalline layer of ferromagnetic material formed on top of the at least one seed layer (structure). An advantage of having the polycrystalline layer formed on the seed layer is that the seed layer may promote better growth and alignment of the polycrystalline grains. This may result in improved magnetic properties, such as reduced coercivity and enhanced stability, which in turn may enhance the performance and accuracy of the TMR sensor in detecting magnetic fields.

In some implementations, the seed layer structure may include or act as a dusting layer between the lattice matching ferromagnetic layer and the polycrystalline layer of ferromagnetic material. A dusting layer may be a thin layer of material applied between two other layers in a multilayer structure. A purpose of the dusting layer may be to modify the interface properties between the adjacent layers. It can influence various characteristics, such as magnetic coupling, electron scattering, etc.

In some implementations, the seed layer structure is electrically conductive. An advantage of having an electrically conductive seed layer structure is that it may ensure Current-Perpendicular-to-Plane (CPP) electrical connectivity within the TMR sensor.

In some implementations, the seed layer structure (e.g., including single seed layer or a combination of two seed layers) of the multilayer sensing structure is thinner than the polycrystalline layer of ferromagnetic material of the multilayer sensing structure. That is, the seed layer structure's thickness may be less than the thickness of the polycrystalline layer of ferromagnetic material. For example, the seed layer structure's thickness may be in range from 0.5 to 5 nm. This may help in controlling the growth and properties of the ferromagnetic layer. A thinner seed layer structure is preferred to allow the use of a thicker polycrystalline ferromagnetic layer with high saturation magnetization (Ms) to maximize the linear sensing range. This may improve the sensor's performance and accuracy.

In some implementations, the seed layer structure includes a ferromagnetic material, e.g., NiFe, or a material that allows interlayer exchange coupling, such as Ta, Ru, Ir, Pt, Pd, Au, Ag, and Cu. These materials may be selected for their good thin film deposition characteristics and ability to act as effective seed layers. They may enhance a crystalline structure, reduce grain size, and improve magnetic properties of the layers deposited on them. This may ensure high-quality, reliable performance of the multilayer structure in TMR sensors.

In some implementations, the polycrystalline layer of ferromagnetic material is selected from the group of CoFe, CoFeTa, CoFeB, and NiFe (or any other ferromagnetic alloy). This means that the ferromagnetic layer can be made from any of these materials. The materials may be chosen for their good magnetic properties. Using CoFe, CoFeTa, CoFeB, or NiFe may improve the sensor's sensitivity and accuracy. Depending on the Fe, Ta or B content, these materials have high saturation magnetization, which helps increasing the linear range of the magnetic field sensor. They also have good stability, which ensures consistent sensor performance over time. This selection may enhance the overall efficiency and reliability of the TMR sensor.

In some implementations, the multilayer sensing structure includes a lattice matching ferromagnetic layer (e.g., CoFeB) formed on the tunnel barrier, at least one seed layer structure formed on the lattice matching ferromagnetic layer (e.g., CoFeB), and the polycrystalline ferromagnetic layer formed on the seed layer. The lattice matching ferromagnetic layer may be directly on top of the tunnel barrier. The seed layer structure may then be placed on this lattice matching layer. Finally, the polycrystalline ferromagnetic layer may be formed on the seed layer structure. This arrangement may improve the sensor's performance. The lattice matching layer should match with the MgO crystal structure to ensure a high TMR-effect. The seed layer structure may enhance the growth and quality of the polycrystalline layer. The polycrystalline layer may improve the sensor's linear range and reliability.

In some implementations, the lattice matching ferromagnetic layer and the polycrystalline ferromagnetic layer are ferromagnetic interlayer exchange coupled via the at least one seed layer (structure). This means that the two ferromagnetic layers may influence each other's magnetic properties through the seed layer structure between them. This may be important to have one vortex magnetization in the multilayer to enable magnetic field sensing. The interlayer exchange coupling (RKKY) may help maintain consistent magnetic properties across the layers, enhancing overall sensor performance.

In some implementations, the multilayer sensing structure further includes at least one further seed layer (structure) formed on the polycrystalline layer of ferromagnetic material, and a further polycrystalline layer of ferromagnetic material formed on the further seed layer. The further seed layer (structure) may be placed on top of the initial polycrystalline ferromagnetic layer. The further polycrystalline layer of ferromagnetic material may then be added on top of this further seed layer (structure). These additional layers may improve the sensor's performance by enhancing magnetic properties and stability. The further seed layer (structure) may ensure proper growth and structure of the additional polycrystalline ferromagnetic layer. The additional polycrystalline ferromagnetic layer may improve the soft magnetic behavior and lower the hysteresis. This setup may provide better magnetic field measurement and makes the sensor more reliable and efficient.

In some implementations, the TMR sensor further includes a capping layer formed on the multilayer sensing structure. This means that an additional protective layer may be added on top of the entire multilayer stack. This capping layer may protect the underlying layers from damage and oxidation. It may help maintain the sensor's performance and longevity. The capping layer may ensure that the sensor remains stable and reliable over time. It may provide an extra layer of durability, making the sensor more robust in various environments.

In some implementations, the reference system includes an antiferromagnetic layer and a pinned ferromagnetic layer. The antiferromagnetic layer may keep the magnetization of the pinned ferromagnetic layer fixed in one direction. This may provide a stable reference point for measuring changes in the magnetic field. Having a fixed magnetization may help improve the sensor's accuracy.

According to a further aspect, the present disclosure provides a method for manufacturing a TMR sensor. The method includes forming a substrate, forming a reference system on the substrate, forming a tunnel barrier on the reference system, and forming a multilayer sensing structure on the tunnel barrier. The multilayer sensing structure includes at least one seed layer and at least one layer of polycrystalline ferromagnetic material with a saturation magnetization of at least 1.5 Tesla.

The proposed TMR sensor integrates seed layers and laminated films within the free layer (FL) of a (vortex-based) TMR sensor. This integration may use ferromagnetic materials with high saturation magnetization, such as CoFe, to enhance the linear range of the sensor. By incorporating specific seed layers and laminated films, the grain size of CoFe or NiFe may be reduced, making the material more soft-magnetic and enhancing its performance.

### BRIEF DESCRIPTION OF THE DRAWINGS

Some examples of apparatuses and/or methods will be described in the following by way of example only, and with reference to the accompanying figures, in which

FIG. 1A shows a schematic representation of a layer stack of a magnetoresistive sensor element;

FIG. 1B shows a schematic representation of a magnetoresistive sensor element with a magnetic free layer with vortex magnetization;

FIGS. 2A and 2B illustrate vortex annihilation and nucleation fields for different free layer materials;

FIG. 3A shows a magnetoresistive sensor element according to a first implementation of the present disclosure;

FIG. 3B shows a magnetoresistive sensor element according to a second implementation of the present disclosure;

FIG. 4 shows a magnetoresistive sensor element according to a third implementation of the present disclosure;

FIGS. 5A and 5B show magnetic hysteresis loops illustrating the impact of different seed layers on coercivity and magnetic properties of magnetoresistive sensor elements; and

FIGS. 6A and 6B illustrate a reduction of coercivity using NiFe or Ru seed layers.

### DETAILED DESCRIPTION

Some examples are now described in more detail with reference to the enclosed figures. However, other possible examples are not limited to the features of these implementations described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, e.g., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

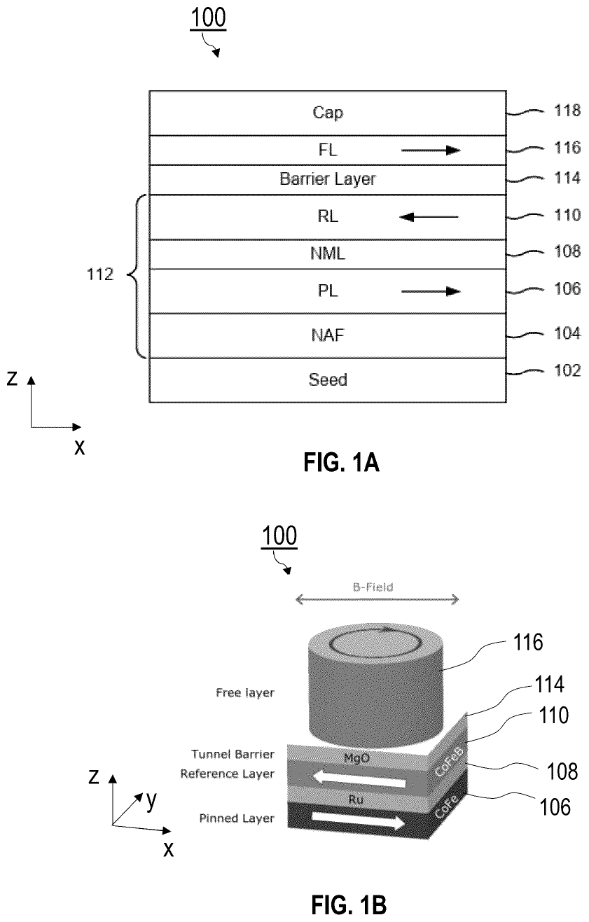

FIG. 1A shows an example of a layer stack of a magnetoresistive sensor element 100 according to one or more implementations.

The magnetoresistive sensor element 100 can, for example, be a TMR sensor element with a bottom-pinned spin-valve (BSV) configuration. GMR sensor elements are also possible. The magnetoresistive sensor element 100 can be arranged on a semiconductor substrate (not shown) of a magnetoresistive sensor. In the description using a Cartesian coordinate system with mutually perpendicular coordinate axes x, y, and z, the layers of the layer stack extend laterally in an xy-plane spanned by the x- and y-axes. Thus, lateral dimensions (e.g., lateral distances, lateral cross-sectional areas, lateral surfaces, lateral extensions, lateral displacements, etc.) can refer to dimensions in the xy-plane, and vertical dimensions can refer to dimensions in the z-direction, perpendicular to the xy-plane. For example, the vertical extension of a layer in the z-direction can be referred to as the layer thickness.

The layer stack of the magnetoresistive sensor element 100 comprises at least one reference layer with a reference magnetization (e.g., a reference direction in the case of GMR or TMR technology). The reference magnetization is a magnetization direction that provides a sensor direction corresponding to a sensor axis of the magnetoresistive sensor element 100. The reference layer and thus the reference magnetization define a sensor plane. The sensor plane can, for example, be defined by the xy-plane. Thus, the x-direction and the y-direction can be referred to as “in-plane” concerning the sensor plane, and the z-direction can be referred to as “out-of-plane” concerning the sensor plane.

Accordingly, in the case of a GMR sensor element or a TMR sensor element, the resistance of the magnetoresistive sensor element 100 is minimal when the free magnetization of a magnetic free layer points exactly in the same direction as the reference magnetization (e.g., the reference direction), and the resistance of the magnetoresistive sensor element 100 is maximal when the free magnetization of the magnetic free layer points exactly in the opposite direction to the reference magnetization. The alignment of the free magnetization of the magnetic free layer is variable in the presence of an external magnetic field. Thus, the resistance of the magnetoresistive sensor element 100 can vary based on the influence of the external magnetic field on the free magnetization of the free layer.

From bottom to top, the magnetoresistive sensor element 100 can include an optional seed layer 102, which can be used to influence and/or optimize stack growth. In some implementations, the seed layer 102 can consist of copper (Cu), tantalum (Ta), ruthenium (Ru), or a combination thereof. In the example shown, a natural antiferromagnetic (NAF) layer 104 is formed or otherwise arranged on the seed layer 102. The NAF layer 104 can consist of platinum-manganese (PtMn), iridium-manganese (IrMn), nickel-manganese (NiMn), or the like. The thickness of the NAF can, for example, range from 5 nm to 50 nm.

Furthermore, a pinned layer (PL) 106 can be formed or otherwise arranged on the NAF layer 104. The pinned layer 106 can consist of a ferromagnetic material such as cobalt-iron (CoFe) or cobalt-iron-boron (CoFeB). A contact between the NAF layer 104 and the pinned layer 106 can induce an effect known as the exchange bias effect, causing the magnetization of the pinned layer 106 to align in a preferred direction (e.g., in the x-direction, as shown). The magnetization of the pinned layer 106 can be referred to as pinned magnetization. The pinned layer 106 can exhibit a linear magnetization pattern in the xy-plane (e.g., a homogeneous alignment in one direction) that is permanently fixed.

The magnetoresistive sensor element 100 also includes a non-magnetic layer (NML), referred to as a coupling interlayer 108. In one possible implementation, the coupling interlayer 108 can include ruthenium (Ru), iridium (Ir), copper (Cu), copper alloys, or similar materials. Other materials (e.g., paramagnets) are also possible. A magnetic (e.g., ferromagnetic) reference layer (RL) 110 can be formed or otherwise arranged on the coupling interlayer 108. The thickness of the pinned layer 106 and the magnetic reference layer 110 can range from 1 nm to 10 nm, for example.

Accordingly, the coupling interlayer 108 can be arranged between the pinned layer 106 and the magnetic reference layer 110 to spatially separate the pinned layer 106 and the magnetic reference layer 110 in the vertical direction. Furthermore, the coupling interlayer 108 can provide interlayer exchange coupling (e.g., an antiferromagnetic Ruderman-Kittel-Kasuya-Yosida (RKKY) coupling) between the pinned layer 106 and the magnetic reference layer 110 to form an artificial antiferromagnet. Consequently, the magnetization of the magnetic reference layer 110 can align and be maintained in a direction that is antiparallel or opposite to the magnetization of the pinned layer 106 (e.g., in the x-direction, as shown). The magnetization of the magnetic reference layer 110 can be referred to as reference magnetization.

Since the NAF layer 104 is configured to align and fix the magnetization of the pinned layer 106 in a certain direction, and the coupling interlayer 108 is configured to align and fix the magnetization of the magnetic reference layer 110 in an opposite direction, it can be the that the NAF layer 104 is configured to maintain the magnetization of the pinned layer 106 (e.g., a fixed magnetization) in a first magnetic orientation and to maintain the magnetization of the magnetic reference layer 110 (e.g., a fixed reference magnetization) in a second magnetic orientation. The magnetic reference layer 110 can exhibit a linear magnetization pattern in a specific direction in the xy-plane when the pinned layer 106 exhibits a linear magnetization pattern in an antiparallel direction. Thus, the NAF layer 104, the pinned layer 106, the coupling interlayer 108, and the magnetic reference layer 110 form a magnetic reference layer system 112 of the magnetoresistive sensor element 100.

The magnetoresistive sensor element 100 additionally includes a barrier layer 114 (e.g., a tunnel barrier) vertically arranged between the reference layer system 112 and a free magnetic layer 116. The barrier layer 114 can, for example, be formed or otherwise arranged on the magnetic reference layer 110 of the reference layer system 112, and the free magnetic layer 116 can be formed or otherwise arranged on the barrier layer 114.

The barrier layer 114 can consist of a non-magnetic material. In some implementations, the barrier layer 114 can be an electrically insulating tunnel barrier layer. For example, the barrier layer 114 can be a tunnel barrier layer used to generate a TMR effect. The barrier layer 114 can consist of magnesium oxide (MgO) or another material with similar properties.

The material of the free magnetic layer 116 can be an alloy of a ferromagnetic material, such as CoFe, CoFeTa, CoFeB, NiFe, or a plurality of layers. The free magnetic layer 116 has a free magnetization that is variable in the presence of an external magnetic field. Therefore, the free magnetic layer 116 can be referred to as a sensor layer, as changes in the free magnetization can be used to determine a measured variable. Furthermore, the free magnetization has a magnetic standard orientation in a ground state (such as vortex magnetization). In some implementations, the magnetoresistive sensor element 100 can include a free magnetic system comprising a plurality of layers (e.g., two or more free magnetic layers) that together act as the free magnetic layer. In this case, the free magnetic layers of the free magnetic system are magnetically coupled to each other. Thus, the free magnetic system can function as a free magnetic layer but also consist of several layers. The free magnetic system has a free magnetization, where the free magnetization is variable in the presence of the external magnetic field.

A capping layer 118, such as tantalum (Ta), tantalum nitride (TaN), ruthenium (Ru), titanium (Ti), titanium nitride (TiN), platinum (Pt), or the like, can be formed or otherwise arranged on the free magnetic layer 116 to form an upper layer of the magnetoresistive sensor element 100.

The seed layer 102 can serve as a bottom electrode or establish an electrical contact with a bottom electrode (not shown) of the magnetoresistive sensor element 100. The capping layer 118 can establish an electrical contact with a top electrode (not shown) of the magnetoresistive sensor element 100. The barrier layer 114 can be configured so that electrons can tunnel between the reference layer system 112 and the free magnetic layer 116 when a bias is applied to the electrodes of the magnetoresistive sensor element 100 (not shown) to generate a magnetoresistance effect (e.g., a TMR effect).

As mentioned above, FIG. 1A serves merely as an example of a magnetoresistive sensor element. Other examples can deviate from the description in FIG. 1. The number and arrangement of the components shown in FIG. 1A is an example. In practice, the magnetoresistive sensor element 100 can contain additional elements or layers.

FIG. 1B shows a simplified perspective view of the magnetoresistive sensor element 100, in which the free magnetic layer 116 is formed in the shape of a circular disk to spontaneously form a vortex magnetization in the ground state. The circular disk-shaped free magnetic layer 116 has a diameter D, which can, for example, range from several hundred nm to 10 μm. The free magnetic layer 116 also has a thickness t in the range of, for example, 10 nm to 100 or 200 nm. Providing a layer with this structure can lead to the spontaneous formation of a closed flux magnetization pattern in the free magnetic layer 116. The occurrence of such a field can also be called a vortex state or a vortex configuration. The vortex state depends on the aspect ratio of thickness t and diameter D and can be achieved by selecting the disk thickness t in the range of, for example, 20 nm to 200 nm and the disk diameter D between 100 nm and 3 μm. The vortex spin-valve structure is not limited to the TMR effect; it can also be realized, for example, through a GMR structure.

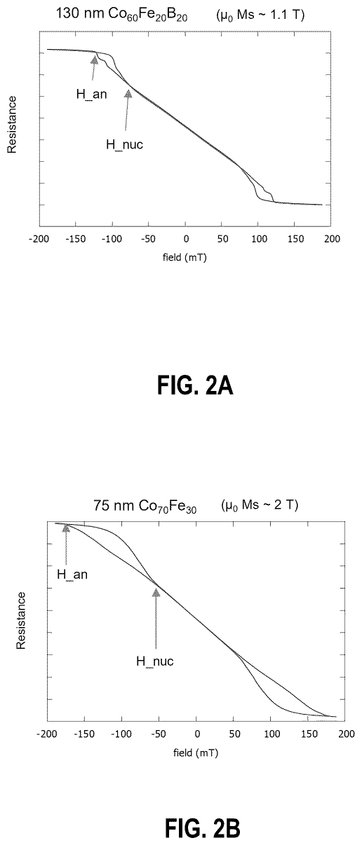

FIGS. 2A and 2B illustrate annihilation fields (H_an) and nucleation fields (H_nuc) for different free layer materials in magnetoresistive sensor elements 100.

The annihilation field is a specific external magnetic field strength required to eliminate a vortex state in a magnetic material. When this field is applied, the vortex structure in the free magnetic layer 116 disappears. The nucleation field is a specific external magnetic field strength required to create a vortex state in a magnetic material. When this field is applied, the vortex structure forms in the free magnetic layer 116. As can be seen in FIGS. 2A and 2B there is hysteresis in the context of annihilation and nucleation fields. Hysteresis means there is a difference between the field strength needed to create a vortex (nucleation field) and the field strength needed to eliminate it (annihilation field). Typically, the nucleation field (H_nuc) is different from the annihilation field (H_an). This difference causes a hysteresis loop when the external magnetic field is cycled. It shows that the vortex state is stable over a (linear) range of external magnetic fields. While annihilation fields (H_an) of around 120 mT may be achieved with 130 nm thick Co₆₀Fe₂₀B₂₀ free magnetic layers 116, annihilation fields (H_an) larger than 140 mT or even larger than 170 mT may be needed for future applications. When using Co₇₀Fe₃₀ as material for the free magnetic layer 116, the annihilation field (H_an) may be increased. However, the nucleation field (H_nuc) is strongly reduced to about 50 mT with CoFe (see FIG. 2B). However, nucleation fields (H_nuc) larger than 80 mT or even larger than 120 mT may be needed for future applications.

The linear range of the magnetoresistive sensor element 100 is the span of magnetic field strengths between the negative and positive nucleation field where the magnetoresistive sensor element 100 operates effectively and its response is proportional to the applied external magnetic field. Within this range, the vortex structure of the free magnetic layer 116 remains stable, providing accurate and linear measurements of the external magnetic field. Outside this range, as the external magnetic field approaches the nucleation or annihilation field, the sensor's response may become nonlinear, leading to less accurate measurements or is not even in the vortex state if the external magnetic field was exceeding the annihilation field before. Thus, the stability provided by the nucleation and annihilation fields directly impacts the sensor's linear operating range.

For vortex-based sensors, the linear range is approximately proportional to Mₛt/D, wherein Mₛ denotes the saturation magnetization. Thus, the linear range can either be increased by increasing the thickness t or reducing the diameter D of the free magnetic layer 116. Due to technical limitations within process integration, the FL thickness cannot be increased at will. On the other hand, the reduction of the diameter may also be limited, e.g., by lithography. In addition increasing the thickness t of the free magnetic layer 116 is expensive because of deposition and etching time. Thus, implementations of the present disclosure aim at increasing the linear range by increasing the saturation magnetization Mₛ of the free magnetic layer 116 which will also be referred to as sensing layer in the following. Saturation magnetization refers to the maximum magnetization a material can achieve when exposed to an external magnetic field. It represents the point at which all magnetic moments in the material are aligned with the external field.

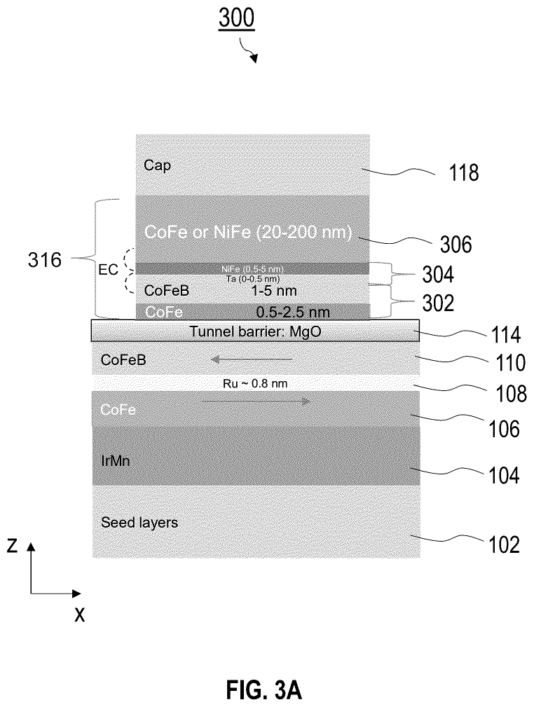

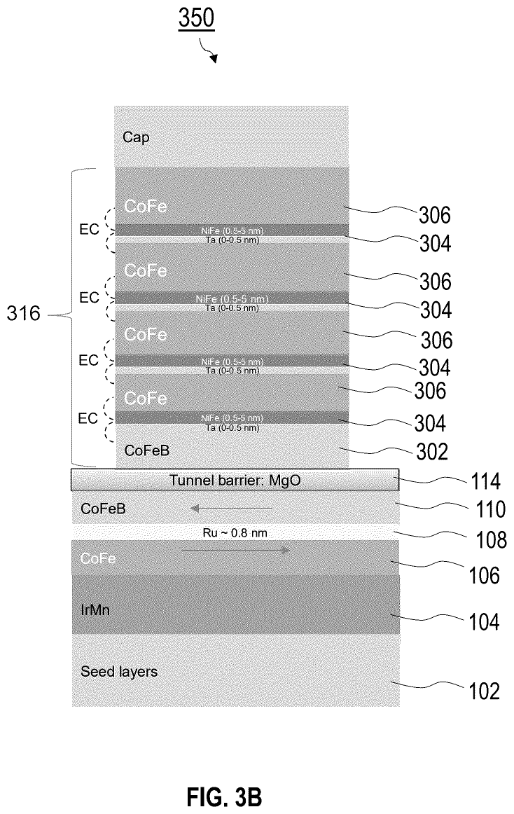

FIG. 3A shows a magnetoresistive sensor element 300 according to a first implementation of the present disclosure. The magnetoresistive sensor element 300 may be a TMR sensor element.

The magnetoresistive sensor element 300 can be arranged on a semiconductor substrate (not shown) of a magnetoresistive sensor. From bottom to top, the magnetoresistive sensor element 300 can include seed layer 102, which can be used to influence and/or optimize stack growth. In some implementations, the seed layer 102 can consist of copper (Cu), tantalum (Ta), ruthenium (Ru), or a combination thereof.

In the example shown, a natural antiferromagnetic (NAF) layer 104 is formed or otherwise arranged on the seed layer 102. The NAF layer 104 can consist of platinum-manganese (PtMn), iridium-manganese (IrMn), nickel-manganese (NiMn), or the like.

Furthermore, pinned layer (PL) 106 can be formed or otherwise arranged on the NAF layer 104. The pinned layer 106 can consist of a ferromagnetic material such as cobalt-iron (CoFe) or cobalt-iron-boron (CoFeB). A contact between the NAF layer 104 and the pinned layer 106 can induce the exchange bias effect.

The magnetoresistive sensor element 300 also includes a non-magnetic layer (NML), referred to as a coupling interlayer 108. In one possible implementation, the coupling interlayer 108 can include ruthenium (Ru), iridium (Ir), copper (Cu), copper alloys, or similar materials. Other materials (e.g., paramagnets) are also possible.

A magnetic (e.g., ferromagnetic) reference layer (RL) 110 can be formed or otherwise arranged on the coupling interlayer 108. The thickness of the pinned layer 106 and the magnetic reference layer 110 can range from 1 nm to 10 nm, for example.

Accordingly, the coupling interlayer 108 can be arranged between the pinned layer 106 and the magnetic reference layer 110 to spatially separate the pinned layer 106 and the magnetic reference layer 110 in the vertical direction. The coupling interlayer 108 can induce RKKY coupling between the pinned layer 106 and the magnetic reference layer 110 to form an artificial antiferromagnet. Consequently, the magnetization of the magnetic reference layer 110 can align and be maintained in a direction that is antiparallel or opposite to the magnetization of the pinned layer 106 (e.g., in the x-direction, as shown). The magnetization of the magnetic reference layer 110 can be referred to as reference magnetization. The magnetic reference layer 110 can exhibit a linear magnetization pattern in a specific direction in the xy-plane when the pinned layer 106 exhibits a linear magnetization pattern in an antiparallel direction. Thus, the NAF layer 104, the pinned layer 106, the coupling interlayer 108, and the magnetic reference layer 110 form the magnetic reference layer system 112 of the magnetoresistive sensor element 300.

The magnetoresistive sensor element 300 additionally includes barrier layer 114 (e.g., a tunnel barrier) vertically arranged between the reference layer system 112 and a multilayer sensing structure 316 (which may also be referred to as free magnetic layer(s), similar to layer 116). The barrier layer 114 can, for example, be formed or otherwise arranged on the magnetic reference layer 110 of the reference layer system 112, and the multilayer sensing structure 316 can be formed or otherwise arranged on the barrier layer 114. The barrier layer 114 can consist of a non-magnetic material. In some implementations, the barrier layer 114 can be an electrically insulating tunnel barrier layer. For example, the barrier layer 114 can be a tunnel barrier layer used to generate a TMR effect. The barrier layer 114 can consist of magnesium oxide (MgO) or another material with similar properties.

The multilayer sensing structure 316 on top of barrier layer 114 may act as a free magnetic system comprising a plurality of layers that together act as the free magnetic layer. Thus, the free magnetic system can function as a free magnetic layer but also consist of several layers. The free magnetic system has a free magnetization, where the free magnetization is variable in the presence of the external magnetic field.

The multilayer sensing structure 316 comprises a ferromagnetic layer 302 formed on the barrier layer 114. Ferromagnetic layer 302 may be amorphous as deposited, but may become crystalline after annealing, e.g., may adapt to the barrier layer (e.g., MgO) crystal structure during annealing. The crystalline structure of the ferromagnetic layer 302 may be a lattice matching ferromagnetic layer with a lattice structure matching a lattice structure of the barrier layer (e.g., MgO) 114. The material of the ferromagnetic layer 302 can be an alloy of a ferromagnetic material, such as CoFe, CoFeB, or NiFe, or a combination thereof. The example illustrated in FIG. 3A comprises a second ferromagnetic layer (CoFeB-layer) on top of a first crystalline ferromagnetic layer (CoFe-layer). A thickness of the CoFe-layer may be in a range from 0.5 nm to 2.5 nm, for example. A thickness of the CoFeB-layer may be in a range from 1 nm to 5 nm, for example.

The multilayer sensing structure 316 further comprises at least one seed layer 304 formed or otherwise arranged on top the ferromagnetic layer(s) 302. The material of the seed layer 304 may be selected from the group of Ta, NiFe, Ru, Ir, Pt, Pd, Au, Ag, and Cu. A thickness of the seed layer 304 may be in the range of 0.5 to 5 nm, for example. Seed layer 304 can be used to influence and/or optimize growth of a layer 306 of ferromagnetic material with a saturation magnetization of at least 1.5 Tesla and/or low coercivity/hysteresis.

The example illustrated in FIG. 3A shows a seed layer structure 304 comprising a NiFe-layer on top of a Ta-layer. A thickness of the Ta-layer (first seed layer) may be in a range from 0 nm to 0.5 nm, for example. A thickness of the NiFe-layer (second seed layer) may be in a range from 0.5 nm to 5 nm, for example.

The multilayer sensing structure 316 further comprises the layer 306 of ferromagnetic material (with a saturation magnetization of at least 1.5 Tesla) formed or otherwise arranged on the seed layer structure 304. The layer 306 of ferromagnetic material may be a polycrystalline ferromagnetic layer formed on the seed layer structure 304. The polycrystalline structure may have multiple small crystals or grains, which can improve the overall magnetic properties and stability of the layer 306. The seed layer structure 304 may help control the grain size and orientation of the polycrystalline layer, leading to a soft magnetic behavior with low hysteresis. The material of the layer 306 of ferromagnetic material may be selected from the group of CoFe, CoFeTa, CoFeB, and NiFe, or any other ferromagnetic alloy. A thickness of the layer 306 of ferromagnetic material may be larger than the seed layer 304. For example, the thickness of the layer 306 of ferromagnetic material may be at least five times the thickness of the seed layer 304. The thickness of the layer 306 of ferromagnetic material may be in a range from 20 to 200 nm.

The ferromagnetic layer(s) 302 and the polycrystalline layer 306 of ferromagnetic material may be ferromagnetic interlayer exchange coupled (IEC) via the seed layer structure 304. This strong coupling may force the ferromagnetic layer(s) 302 to have the same magnetization as the polycrystalline layer 306 so that a changed magnetization state due to an external magnetic field is transferred into a changed resistance via the TMR-effect. A vortex magnetization may be formed in the multilayer sensing structure 316. Due to the ferromagnetic coupling between 306 and 302, the vortex state is also in ferromagnetic layer(s) 302. However, mainly polycrystalline layer 306 may be responsible for the vortex state.

The seed layer structure 304 may help to lower a grain size of the layer 306 of ferromagnetic material. When the grain size is small, typically in the nanometer range, the ferromagnetic material tends to have lower coercivity. Coercivity is a measure of the resistance of a ferromagnetic material to becoming demagnetized. It is the intensity of the applied magnetic field required to reduce the magnetization of the material to zero after the material has been magnetized to its saturation point. In simpler terms, coercivity indicates how strong an external magnetic field needs to be to completely demagnetize the material. High coercivity means the material is hard to demagnetize and retains its magnetization well, also known as hard magnetic material, while low coercivity means it is easier to demagnetize, also known as soft magnetic material.

A capping layer 118 may be formed on top of the multilayer sensing structure 316. The skilled person having benefited from the present disclosure will appreciate that the number of seed layers 304 and polycrystalline layers 306 of ferromagnetic material may deviate from the illustrated implementations.

FIG. 3B shows a magnetoresistive sensor element 350 according to a second implementation of the present disclosure. The magnetoresistive sensor element 300 may be a TMR sensor element.

The magnetoresistive sensor element 350 of FIG. 3B differs from FIG. 3A in that the multilayer sensing structure 316 is formed differently. A single crystalline CoFeB-layer 302 is formed on the barrier layer 114. The crystalline structure of the CoFeB-layer 302 may be a lattice structure matching a lattice structure of the barrier layer (e.g., MgO) 114.

The magnetoresistive sensor element 350 of FIG. 3B has a first seed layer (structure) 304 formed on the CoFeB-layer 302. The first seed layer (structure) 304 comprises a NiFe-layer on top of a Ta-layer. A thickness of the Ta-layer may be in a range from 0 nm to 0.5 nm, for example. A thickness of the NiFe-layer may be in a range from 0.5 nm to 5 nm, for example.

The magnetoresistive sensor element 350 of FIG. 3B has a first polycrystalline layer 306 of ferromagnetic material (with a saturation magnetization of at least 1.5 Tesla) formed or otherwise arranged on the first seed layer (structure) 304. The ferromagnetic layer 302 and the first polycrystalline layer 306 of ferromagnetic material may be ferromagnetic coupled (exchange coupling, EC) via the first seed layer(s) 304.

The magnetoresistive sensor element 350 of FIG. 3B has a second seed layer (structure) 304 formed on the first polycrystalline layer 306 of ferromagnetic material. The second seed layer (structure) 304 comprises a NiFe-layer on top of a Ta-layer.

The magnetoresistive sensor element 350 of FIG. 3B has a second polycrystalline layer 306 of ferromagnetic material formed or otherwise arranged on the second seed layer (structure) 304. The first polycrystalline layer 306 and the second polycrystalline layer 306 of ferromagnetic material may be ferromagnetic coupled (EC) via the second seed layer(s) 304.

The magnetoresistive sensor element 350 of FIG. 3B has a third seed layer (structure) 304 formed on the second polycrystalline layer 306 of ferromagnetic material. The third seed layer (structure) 304 comprises a NiFe-layer on top of a Ta-layer.

The magnetoresistive sensor element 350 of FIG. 3B has a third polycrystalline layer 306 of ferromagnetic material formed or otherwise arranged on the third seed layer (structure) 304. The second polycrystalline layer 306 and the third polycrystalline layer 306 of ferromagnetic material may be ferromagnetic coupled (EC) via the third seed layer(s) 304.

The magnetoresistive sensor element 350 of FIG. 3B has a fourth seed layer (structure) 304 formed on the third polycrystalline layer 306 of ferromagnetic material. The fourth seed layer (structure) 304 comprises a NiFe-layer on top of a Ta-layer.

The magnetoresistive sensor element 350 of FIG. 3B has a fourth polycrystalline layer 306 of ferromagnetic material formed or otherwise arranged on the fourth seed layer (structure) 304. The fourth polycrystalline layer 306 and the third polycrystalline layer 306 of ferromagnetic material may be ferromagnetic coupled (EC) via the fourth seed layer(s) 304.

A capping layer 118 is formed on top of the multilayer sensing structure 316. The skilled person having benefited from the present disclosure will appreciate that the number of seed layers 304 and polycrystalline layers 306 of ferromagnetic material may deviate from the illustrated implementations.

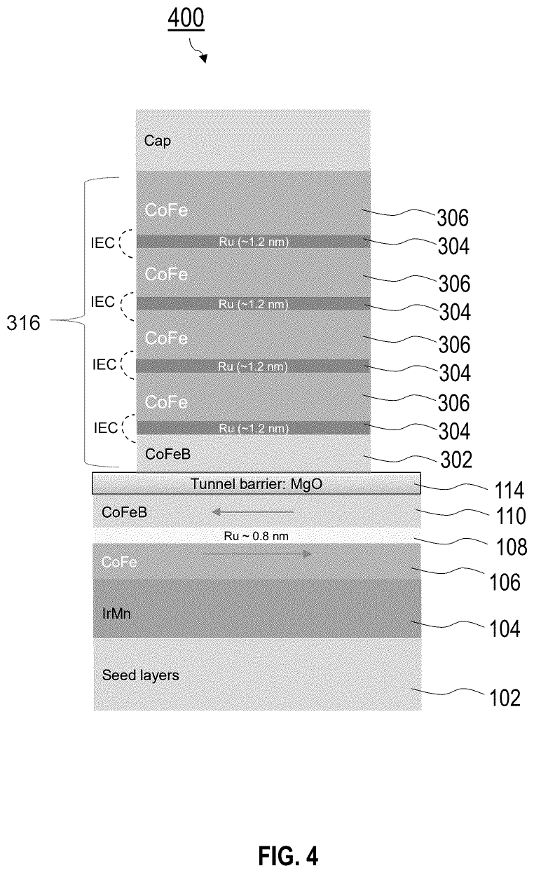

FIG. 4 shows a magnetoresistive sensor element 400 according to a third implementation of the present disclosure. The magnetoresistive sensor element 400 may be a TMR sensor element.

Magnetoresistive sensor element 400 differs from magnetoresistive sensor element 350 in the material of the seed layer 304. While the magnetoresistive sensor element 350 uses a seed layer 304 comprising a combination of Ta- and NiFe-sublayers, magnetoresistive sensor element 400 uses seed layers 304 made of Ru. A thickness of the Ru-seed layer(s) 304 may be in a range from 1 nm to 1.5 nm (e.g., 1.2 nm), for example.

While FIG. 4 shows a multilayer sensing structure 316 with a single CoFeB-layer 302, four seed layers 304, and four polycrystalline layers 306 of ferromagnetic material. The polycrystalline layer 306 of ferromagnetic material may be ferromagnetic interlayer exchange coupled (IEC) via the seed layer 304. The skilled person having benefit from the present disclosure will appreciate that also more or less seed layers 304 and polycrystalline layers 306 could be used. For example, the Ru-seed layer 304 of FIG. 4 could also be used to replace the seed layer (structure) 304 of FIG. 3A comprising the NiFe-layer on top of the Ta-layer.

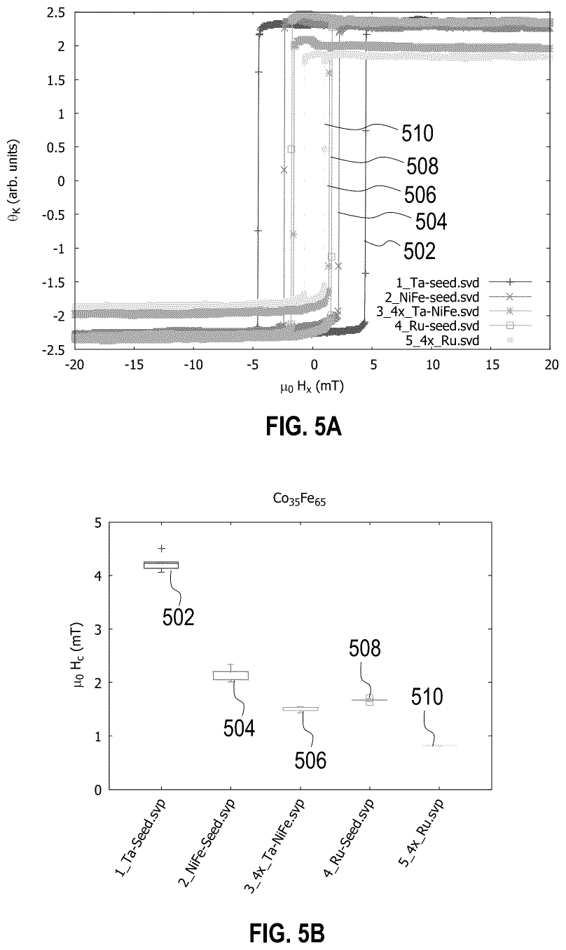

FIG. 5A shows magnetic hysteresis loops of various TMR sensors with different seed layers 304 and at least one layer 306 of Co₃₅Fe₆₅, indicating how the magnetization (θ_{K}) of the multilayer sensing structure 316 changes with an applied external magnetic field (μ₀Hₓ). Each curve in FIG. 5A corresponds to an extended 80 nm Co₃₅Fe₆₅ multilayer sensing structure 316 with different seed layer material or combined as laminated film:
curve 502 refers to one Ta-seed and one layer 306 of Co₃₅Fe₆₅,
curve 504 refers to one NiFe-seed and one layer 306 of Co₃₅Fe₆₅,
curve 506 refers to four Ta—NiFe seeds and four layers 306 of Co₃₅Fe₆₅ (as shown in FIG. 3B),
curve 508 refers to one Ru seed and one layer 306 of Co₃₅Fe₆₅, and
curve 510 refers to four Ru seeds and four layers 306 of Co₃₅Fe₆₅ (as shown in FIG. 4).

The hysteresis loops show a relationship between the magnetization and the applied external magnetic field. The coercivity is the magnetic field required to reduce the magnetization to zero. It is indicated by the width of the hysteresis loop along the horizontal axis (μ₀Hₓ). The flat regions of the curves at the top and bottom indicate that the film is in saturation where the magnetic moments are fully aligned with the external magnetic field.

The different seed layers affect the shape and width of the respective hysteresis loops, demonstrating their impact on the magnetic properties of the multilayer sensing structure 316. The four Ru seeds curve 510 has the narrowest hysteresis loop (lowest coercivity), followed by the four Ta—NiFe seeds curve 506. The one Ta-seed curve 502 has the widest hysteresis loop (highest coercivity), followed by the one NiFe-seed curve 504. This can also be seen in FIG. 5B.

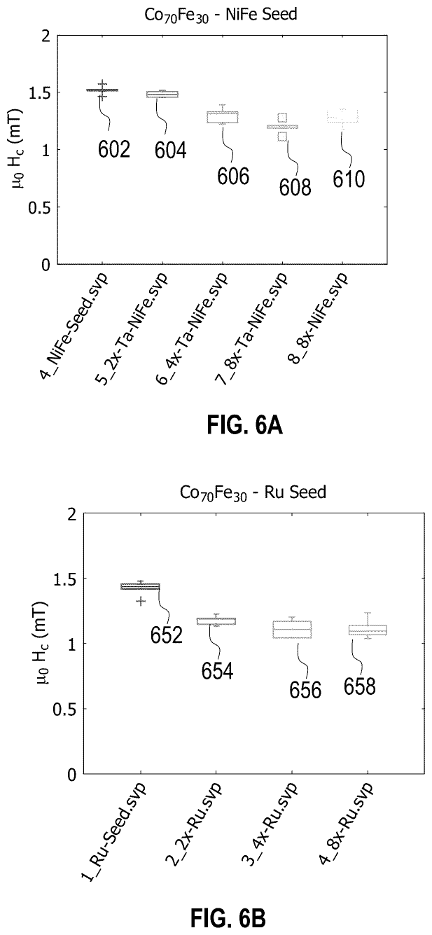

FIGS. 6A and 6B illustrate how Ni₈₀Fe₂₀ or Ru seed layers 304 can reduce Co₇₀Fe₃₀ coercivity from 7 mT (not shown) to 1.5 mT. Curve 602 (one NiFe-seed) shows a coercivity of the multilayer sensing structure 316 of around 1.5 mT. Curve 604 (two Ta—NiFe-seeds) shows a coercivity of the multilayer sensing structure 316 around 1.4 mT. Curve 606 (four Ta—NiFe-seeds) shows a coercivity of the multilayer sensing structure 316 around 1.25 mT. Curve 608 (eight Ta—NiFe-seeds) shows a coercivity of the multilayer sensing structure 316 around 1.2 mT. Curve 610 (eight NiFe-seeds) shows a coercivity of the multilayer sensing structure 316 around 1.25 mT.

Curve 652 (one Ru-seed) shows a coercivity of the multilayer sensing structure 316 of around 1.45 mT. Curve 654 (two Ru-seeds) shows a coercivity of the multilayer sensing structure 316 around 1.15 mT. Curve 656 (four Ru-seeds) shows a coercivity of the multilayer sensing structure 316 around 1.1 mT. Curve 658 (eight Ru-seeds) shows a coercivity of the multilayer sensing structure 316 around 1.1 mT.

If Ni₄₅Fe₅₅ is used for the layer(s) 306 of ferromagnetic material, its coercivity can be reduced by employing NiFe or Ru seed layer(s) 304 (not shown).

If Co₉₀Fe₁₀ is used for the layer(s) 306 of ferromagnetic material, its coercivity can be reduced by employing Ta seed layer(s) 304 (not shown).

A high linear range can be achieved by making use of Free layer (FL) material with high saturation magnetization (Ms) (e.g., larger than 1.5 T). The grain size and hence the soft magnetic behavior of high Ms CoFe or NiFe layers 306 can be reduced with seed layers 304. A lower grain size makes the material more soft magnetic which can be seen in the coercive field. However, for vortex based TMR-sensors, not all seed layers are possible. On the one hand a ferromagnetic layer 302 may be needed at the MgO tunnel barrier 114 to guarantee a high TMR-effect. On the other hand, to enable a vortex magnetization in the FL, the material needs to be ferromagnetically coupled. In addition, the crystal structure of the seed layer 304 should induce the growth of small grains. This may be achieved either with thin layers of Ni₈₀Fe₂₀ for seed and interlayers or with Ru, where the thickness of Ru may be at 1.2 nm for a ferromagnetic interlayer exchange coupling across the Ru layer.

The implementation integrates seed layers and laminated films within the free layer (FL) of a vortex-based TMR sensor. This integration uses ferromagnetic materials with high saturation magnetization, such as CoFe or NiFe, to enhance the linear range of the sensor. By incorporating specific seed layers and laminated films, the grain size of CoFe or NiFe may be reduced, thus creating a magnetically soft material and enhancing its performance.

The aspects and features described in relation to a particular one of the previous examples may also be combined with one or more of the further examples to replace an identical or similar feature of that further example or to additionally introduce the features into the further example.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

### ASPECTS

The following provides an overview of some Aspects of the present disclosure:

Aspect 1: A tunnel magnetoresistance (TMR) sensor, comprising: a substrate; a reference system formed on the substrate; a tunnel barrier formed on the reference system; and a multilayer sensing structure formed on the tunnel barrier, wherein the multilayer sensing structure comprises a seed layer structure and a polycrystalline layer of ferromagnetic material with a saturation magnetization of at least 1.5 Tesla.

Aspect 2: The TMR sensor of Aspect 1, wherein the multilayer sensing structure comprises at least three layers.

Aspect 3: The TMR sensor of any of Aspects 1-2, wherein the multilayer sensing structure comprises a lattice matching ferromagnetic layer with a lattice structure matching a lattice structure of the tunnel barrier.

Aspect 4: The TMR sensor of any of Aspects 1-3, wherein the seed layer structure comprises a single seed layer.

Aspect 5: The TMR sensor of any of Aspects 1-4, wherein the seed layer structure comprises a dusting layer.

Aspect 6: The TMR sensor of any of Aspects 1-5, wherein the seed layer structure is electrically conductive.

Aspect 7: The TMR sensor of any of Aspects 1-6, wherein the seed layer structure is thinner than the polycrystalline layer of ferromagnetic material.

Aspect 8: The TMR sensor of any of Aspects 1-7, wherein a thickness of the polycrystalline layer of ferromagnetic material is at least five times a thickness of the seed layer structure.

Aspect 9: The TMR sensor of any of Aspects 1-8, wherein the seed layer structure comprises a material selected from the group consisting of Ta, NiFe, Ru, Ir, Pt, Pd, Au, Ag, and Cu.

Aspect 10: The TMR sensor of any of Aspects 1-9, wherein the polycrystalline layer of ferromagnetic material selected from the group consisting of CoFe, CoFeTa, CoFeB, and NiFe or any other ferromagnetic alloy.

Aspect 11: The TMR sensor of any of Aspects 1-10, wherein the multilayer sensing structure comprises: a ferromagnetic layer formed on the tunnel barrier; the seed layer structure formed on the ferromagnetic layer; and a polycrystalline ferromagnetic layer formed on the seed layer structure.

Aspect 12: The TMR sensor of Aspect 11, wherein the ferromagnetic layer and the polycrystalline ferromagnetic layer are ferromagnetic interlayer exchange coupled via the seed layer structure.

Aspect 13: The TMR sensor of any of Aspects 1-12, wherein the multilayer sensing structure comprises: a CoFeB layer formed on the tunnel barrier; the seed layer structure formed on the CoFeB layer; and the polycrystalline layer of ferromagnetic material formed on the seed layer structure.

Aspect 14: The TMR sensor of Aspect 13, wherein the multilayer sensing structure further comprises: a further seed layer formed on the polycrystalline layer of ferromagnetic material; and a further polycrystalline layer of ferromagnetic material formed on the further seed layer.

Aspect 15: The TMR sensor of any of Aspects 1-14, further comprising: a capping layer formed on the multilayer sensing structure.

Aspect 16: The TMR sensor of any of Aspects 1-15, wherein the reference system comprises an antiferromagnetic layer and a pinned ferromagnetic layer.

Aspect 17: A method for manufacturing a tunnel magnetoresistance (TMR) sensor, comprising: forming a substrate; forming a reference system on the substrate; forming a tunnel barrier on the reference system; and forming a multilayer sensing structure on the tunnel barrier, wherein the multilayer sensing structure comprises at least one seed layer structure and at least one polycrystalline layer of ferromagnetic material with a saturation magnetization of at least 1.5 Tesla.

Aspect 18: A system configured to perform one or more operations recited in one or more of Aspects 1-17.

Aspect 19: An apparatus comprising means for performing one or more operations recited in one or more of Aspects 1-17.

Aspect 20: A non-transitory computer-readable medium storing a set of instructions, the set of instructions comprising one or more instructions that, when executed by a device, cause the device to perform one or more operations recited in one or more of Aspects 1-17.

Aspect 21: A computer program product comprising instructions or code for executing one or more operations recited in one or more of Aspects 1-17.

1. A tunnel magnetoresistance (TMR) sensor comprising:
a substrate;
a reference system formed on the substrate;
a tunnel barrier formed on the reference system; and
a multilayer sensing structure formed on the tunnel barrier,
wherein the multilayer sensing structure comprises a seed layer structure and a polycrystalline layer of ferromagnetic material with a saturation magnetization of at least 1.5 Tesla.

2. The TMR sensor of claim 1, wherein the multilayer sensing structure comprises at least three layers.

3. The TMR sensor of claim 1, wherein the multilayer sensing structure comprises a lattice matching ferromagnetic layer with a lattice structure matching a lattice structure of the tunnel barrier.

4. The TMR sensor of claim 1, wherein the seed layer structure comprises a single seed layer.

5. The TMR sensor of claim 1, wherein the seed layer structure comprises a dusting layer.

6. The TMR sensor of claim 1, wherein the seed layer structure is electrically conductive.

7. The TMR sensor of claim 1, wherein the seed layer structure is thinner than the polycrystalline layer of ferromagnetic material.

8. The TMR sensor of claim 1, wherein a thickness of the polycrystalline layer of ferromagnetic material is at least five times a thickness of the seed layer structure.

9. The TMR sensor of claim 1, wherein the seed layer structure comprises a material selected from the group consisting of Ta, NiFe, Ru, Ir, Pt, Pd, Au, Ag, and Cu.

10. The TMR sensor of claim 1, wherein the polycrystalline layer of ferromagnetic material selected from the group consisting of CoFe, CoFeTa, CoFeB, and NiFe or any other ferromagnetic alloy.

11. The TMR sensor of claim 1, wherein the multilayer sensing structure comprises;
a ferromagnetic layer formed on the tunnel barrier;
the seed layer structure formed on the ferromagnetic layer; and
a polycrystalline ferromagnetic layer formed on the seed layer structure.

12. The TMR sensor of claim 11, wherein the ferromagnetic layer and the polycrystalline ferromagnetic layer are ferromagnetic interlayer exchange coupled via the seed layer structure.

13. The TMR sensor of claim 1, wherein the multilayer sensing structure comprises:
a CoFeB layer formed on the tunnel barrier;
the seed layer structure formed on the CoFeB layer; and
the polycrystalline layer of ferromagnetic material formed on the seed layer structure.

14. The TMR sensor of claim 13, wherein the multilayer sensing structure further comprises;
a further seed layer formed on the polycrystalline layer of ferromagnetic material; and
a further polycrystalline layer of ferromagnetic material formed on the further seed layer.

15. The TMR sensor of claim 1, further comprising:
a capping layer formed on the multilayer sensing structure.

16. The TMR sensor of claim 1, wherein the reference system comprises an antiferromagnetic layer and a pinned ferromagnetic layer.

17. A method for manufacturing a tunnel magnetoresistance (TMR) sensor, comprising:
forming a substrate;
forming a reference system on the substrate;
forming a tunnel barrier on the reference system; and
forming a multilayer sensing structure on the tunnel barrier,
wherein the multilayer sensing structure comprises at least one seed layer structure and at least one polycrystalline layer of ferromagnetic material with a saturation magnetization of at least 1.5 Tesla.
